(19) United States
(12) Patent Application Publication
(10) Pub. No.: US 2010/0207189 A1
(43) Pub. Date: Aug. 19, 2010

(54) NON-VOLATILE MEMORY DEVICE WITH REDUCED WRITE-ERASE CYCLE TIME

(75) Inventor: Mark D. Kellam, Siler, NC (US)

Correspondence Address: PVF -- RAMBUS, INC.;c/o PARK, VAUGHAN & FLEMING, LLP, 2820 FIFTH STREET, DAVIS, CA, 95618-7759, US

(73) Assignee: RAMBUS INC., Los Altos, CA (US)

(21) Appl. No.: 12/669,157

(22) PCT Filed: May 20, 2008
(86) PCT No.: PCT/US08/64246

§ 371 Date: Jan. 14, 2010

Related U.S. Application Data
(60) Provisional application No. 60/952,379, filed on Jul. 27, 2007.

(51) Int. Cl. H01L 29/788; H01L 21/31

(52) U.S. Cl. 257/316; 257/315; 438/778; 257/E29.3; 257/E21.24

(57) ABSTRACT

A transistor includes a substrate having a surface, where a first region and a second region of the substrate are doped with a first type of dopant, and where a third region of the substrate between the first region and the second region is doped with a second type of dopant. An insulator layer is deposited above a portion of the surface, which includes the third region, and a gate layer is deposited above the insulator layer. An encapsulation layer encloses ends of the gate layer, thereby defining gaps between ends of the insulator layer and the encapsulation layer. These gaps have a depth relative to the ends of the gate layer, with one end of the insulator layer proximate to a boundary between the first region and the third region and another end of the insulator layer proximate to a boundary between the second region and the third region.

### FIELD

The present embodiments relate to memory devices. More specifically, the present embodiments relate to semiconductor memory devices and associated methods for reducing write-erase cycle times without degrading data retention or increasing leakage currents.

### BACKGROUND

Flash memory is an increasingly popular storage technology, which combines the advantages of low cost per bit stored and low power consumption. In most applications, Flash memory is effectively non-volatile, because the retention time during which stored data can be reliably recovered from storage cells is large compared to the timescales associated with these applications.

However, the retention time of Flash memory is also usage-dependent. In particular, as the number of program/erase operations performed on Flash memory increases, the retention time of stored data decreases. For example, operations performed on a given storage cell causes gate-oxide defects to be produced in the given cell. These defects may result in charge leakage. In addition, read operations on storage cells may also result in charge leakage. Overtime, the accumulated charge leakage may degrade signals from these storage cells, thereby reducing the ability to reliably recover the stored data. Consequently, charge leakage associated with defects can limit the total number of usable program/erase operations and read operations for Flash memory devices.

In existing Flash memory devices, this problem is often addressed by using a thick gate-oxide layer. However, while the resulting Flash memory devices have sufficient retention times for many applications, write-erase cycling is often very slow. Moreover, Flash memory devices with a thick gate-oxide layer require higher voltages to operate.

Hence, memory devices and techniques are needed which can be used to store data without the problems listed above.

### BRIEF DESCRIPTION OF THE FIGURES

FIG. 1 is block diagram illustrating an embodiment of a memory device.

FIG. 2A is a graph illustrating an embodiment of an energy-barrier shape associated with an insulator.

FIG. 2B is a graph illustrating an embodiment of boundary polarization.

FIG. 2C is a graph illustrating an embodiment of boundary polarization.

FIG. 2D is a graph illustrating an embodiment of an energy-barrier shape associated with an insulator.

FIG. 3A is a graph illustrating an embodiment of energy-barrier shape as a function of distance.

FIG. 3B is a graph illustrating an embodiment of energy-barrier shape as a function of distance and applied voltage.

FIG. 4 is a graph illustrating tunneling current as a function of gate voltage for an embodiment.

FIG. 5A is a block diagram illustrating an embodiment of a process for fabricating of a memory device.

FIG. 5B is a block diagram illustrating an embodiment of a process for fabricating of a memory device.

FIG. 5C is a block diagram illustrating an embodiment of a process for fabricating of a memory device.

FIG. 5D is a block diagram illustrating an embodiment of a process for fabricating of a memory device.

FIG. 5E is a block diagram illustrating an embodiment of a process for fabricating of a memory device.

FIG. 6 is a flow chart illustrating an embodiment of a process for fabricating a memory device.

FIG. 7 is a block diagram illustrating an embodiment of a memory system.

FIG. 8 is a block diagram illustrating an embodiment of a system.

Note that like reference numerals refer to corresponding parts throughout the drawings.

### DETAILED DESCRIPTION

The following description is presented to enable any person skilled in the art to make and use the disclosed embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present description. Thus, the present description is not intended to be limited to the embodiments shown, but is to be accorded the widest scope consistent with the principles and features disclosed herein.

Embodiments of a memory device (such as a transistor), an integrated circuit that includes the transistor, a chip package that includes the integrated circuit, and a technique for fabricating the transistor are described. This transistor includes a substrate having a surface, where a first region and a second region of the substrate are doped with a first type of dopant, and where a third region of the substrate between the first region and the second region is doped with a second type of dopant. Note that the third region is associated with a channel having a voltage-dependent transconductance. Moreover, an insulator layer is deposited above at least a portion of the surface, which includes the third region, and a gate layer is deposited above the insulator layer. Furthermore, an encapsulation layer encloses ends of the gate layer, thereby defining gaps between ends of the insulator layer and the encapsulation layer. These gaps have a depth relative to the ends of the gate layer, with one end of the insulator layer proximate to a boundary between the first region and the third region and another end of the insulator layer proximate to a boundary between the second region and the third region.

In some embodiments, an atmosphere within the gaps has a pressure less than a pre-determined value. For example, the pre-determined value may be 10⁻⁵ ton. However, in some embodiments the gaps have a pressure approximately between 1 and 10 atmospheres.

In some embodiments, the gaps include a gas. For example, the gas may include argon gas and/or nitrogen gas. Moreover, in some embodiments the gaps include a noble gas.

In some embodiments, the gaps have a dielectric constant of approximately 1.

In some embodiments, the gaps do not overlap the channel.

In some embodiments, the insulator layer has a thickness, and the depth of the gaps approximately equals the thickness. For example, the depth may be less than 20 nm.

In some embodiments, the gaps: reduce tunneling current-induced defects in the insulator layer; improve endurance of the transistor; and/or improve reliability of the transistor.

In some embodiments, the gaps reduce a write-erase cycle time for the memory device without increasing a leakage current between the gate layer and the substrate and/or degrading retention of data stored on the gate layer.

In some embodiments, the one end of the insulator layer is approximately aligned with the boundary between the first region and the third region and the other end of the insulator layer is approximately aligned with the boundary between the second region and the third region.

In some embodiments, the gate layer is a conductor.

In some embodiments, the transistor includes another insulator layer above the gate layer and a control-gate layer above the other insulator layer. In these embodiments, the gate layer may be an insulator.

In some embodiments, a conductance of either of the gaps is larger than a conductance of the insulator layer when a voltage larger than a read-operation voltage is applied between the substrate and the control-gate layer. Moreover, in some embodiments the conductance of either of the gaps is less than the conductance of the insulator layer when a voltage less than or equal to a read-operation voltage is applied between the substrate and the control-gate layer.

Another embodiment provides a system that includes a memory controller and a memory device coupled to the memory controller. This memory device may include the transistor.

Another embodiment provides a computer-readable medium that includes data that specifies the transistor.

Another embodiment provides a method for fabricating the transistor. During this method, a partially completed transistor is received. This partially completed transistor includes the substrate, the insulator layer, and the gate layer. Next, a portion of the insulator layer is removed to define the depth of the gaps and the encapsulation layer is deposited, thereby defining the gaps. Then, an atmospheric condition is set in the gaps and the gaps are sealed.

Another embodiment provides a programmable memory device, which may be included in the integrated circuit, the chip package, and/or the system. This programmable memory device includes a field-effect transistor having a source and a drain at opposite ends of a channel, where the field-effect transistor is defined on a substrate. Note that the insulator layer in the field-effect transistor is deposited above at least a portion of a surface of the substrate, and a gate layer in the field-effect transistor is deposited above the insulator layer. Moreover, the programmable memory device includes an encapsulation layer enclosing ends of the gate layer and the insulator layer thereby defining gaps between ends of the insulator layer and the gate layer, where the gaps extend from ends of the gate layer to approximately the channel.

Embodiments of one or more of these memory devices, integrated circuits, chip modules, systems, and/or techniques may be used in a variety of applications, including: desktop or laptop computers, computer systems, hand-held or portable devices (such as personal digital assistants and/or cellular telephones), set-top boxes, home networks, and/or video-game devices. For example, a memory device (such as the transistor) may be included in computer main memory. Moreover, one or more of these embodiments may be included in a communication channel, such as: serial or parallel wireline or wireless links, wireless metropolitan area networks (such as WiMax), wireless local area networks (WLANs), and/or wireless personal area networks (WPANs).

In some embodiments, one or more of these memory devices, integrated circuits, chip modules, systems, and/or techniques are used in: volatile memory, non-volatile memory, dynamic random access memory (DRAM), static random access memory (SRAM), read-only memory (ROM), erasable programmable read-only memory (EPROM), electrically erasable programmable read-only memory (EEPROM), Flash (such as NAND Flash or NOR Flash), solid-state memory, and/or another type of memory.

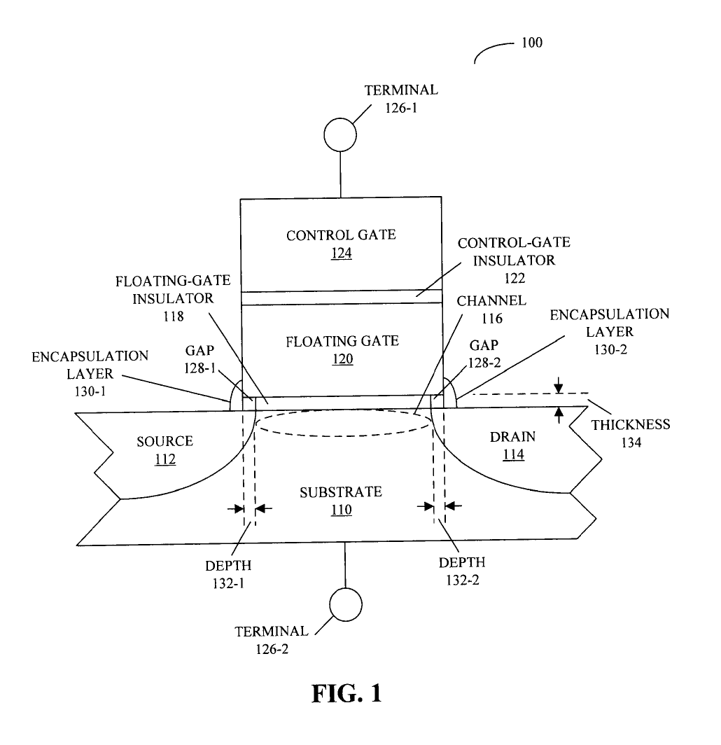

We now describe embodiments of circuits, memory devices and systems to stored data. FIG. 1 presents block diagram illustrating an embodiment of a memory device 100. This device includes a substrate 110, which may be p-type or n-type. Regions on the substrate 110 are doped (for example, using diffusion or implantation) to be a source 112 and a drain 114 in a field-effect transistor. Moreover, the source 112 and the drain 114 may be p-type or n-type. Thus, the field-effect transistor may be PMOS or NMOS. Note that the source 112 and the drain 114 regions define a channel 116 having a voltage-dependent transconductance. In an illustrative embodiment, the memory device 100 is a NAND or NOR Flash memory device, with a p-type substrate and an n-type source and drain (i.e., an NMOS field-effect transistor).

Memory device 100 includes a floating-gate insulator 118 and a floating gate 120 deposited above a surface of the substrate 110. As discussed below, the floating gate 120 may be used to store charge associated with information which is stored in the memory device 100. Note that the stored charge may correspond to binary information or multi-level information. Moreover, the memory device 100 includes a control-gate insulator 122 and a control gate 124 deposited above the floating gate 120.

During operation, voltages are applied between the substrate 110 and the control gate 124 using terminals 126. In particular, during a program operation a large positive voltage may be applied to terminal 126-1 of the previously erased (see below) memory device 100 and charge carriers (such as electrons) may be attracted from the channel 116 towards the floating gate 120 and may traverse the floating-gate insulator 118. These charge carriers may be stored on the floating gate 120. In an exemplary embodiment, the charge carriers traverse an energy barrier associated with the floating-gate insulator 118 by hot-electron injection for a NOR connected memory or field-assisted tunneling (which is henceforth referred to as Fowler-Nordheim tunneling) for a NAND connected memory. Moreover, after the charge is stored, the terminal 126-1 may be set to zero volts.

Similarly, during an erase operation the positive voltage may be applied to terminal 126-2, and the charge stored on the floating gate 120 may be attracted toward the substrate 110 and may traverse the floating-gate insulator 118. In this way, the information stored on the memory device 100 may be erased. Moreover, once the charge on the floating gate 120 is removed, the terminal 126-2 may be set to zero volts.

During a read operation, a smaller positive voltage may be applied to terminal 126-1. In addition, a voltage may be applied between the source 112 and the drain 114 so that the transconductance of the memory device 100 may be determined or measured. Note that the transconductance is dependent on the stored charge on the floating gate 120, which allows the information stored on the memory device 100 to be determined. In NAND Flash embodiments, a group of memory devices, such as the memory device 100, are coupled in series. In these embodiments, neighboring memory devices are pass gates while the memory device 100 is read. Moreover, in NOR Flash embodiments a group of memory devices, such as the memory device 100, are connected in parallel. In these embodiments, each memory device 100 may be individually selected for reading.

Over many program/erase cycles, transport of charge across the floating-gate insulator 118 can produce defects in the floating-gate insulator 118. These defects can lead to current-leakage paths between the floating gate 120 and the substrate 110. This stress-induced leakage current (SILC) can degrade the stored charge and, thus, the stored information, thereby reducing the data retention time associated with the memory device 100. In particular, for a small number of program/erase cycles, the retention time can be many years. However, as the number of program/erase cycles increases retention times progressively decrease due to charge leakage from the floating gate 120. Note that the maximum number of program/erase cycles a given memory device, such as a Flash memory device, can endure and still meet an acceptable data retention time is commonly referred to as the ‘endurance’ of the memory device.

Moreover, the defects in the floating-gate insulator 118 can eventually cause failure of the memory device 100 because the floating gate 120 is no longer well insulated from the substrate 110, i.e., the retention time may be too small to allow the stored information to be reliably recovered. Thus, the memory device 100 can eventually become volatile.

In the discussion that follows, gaps 128 in the floating-gate insulator 118 are used to improve the endurance of the memory device 100 and/or to reduce a write-erase cycle time of the memory device 100. These advantages may be achieved without increasing the leakage current between the floating-gate layer 120 and the substrate 110 and/or without degrading the read-back performance of the memory device 100 (e.g., the read stability and/or the variation in the retention time as a function of the number of read operations is largely unaffected). In particular, during program and/or erase operations some of the charge carriers will be transported to or from the floating gate 120 (for example, by Fowler-Nordheim tunneling) across these gaps (as opposed to the floating-gate insulator 118). Because the current associated with the transport of these charge carriers does not interact with the solid material in the floating-gate insulator 118, the defects in the floating-gate insulator 118 and, thus, the reliability degradation of the memory device 100 are reduced or eliminated (i.e., the memory device 100 may be stable). Moreover, the improved conductivity associated with the gaps during program and/or erase operations may lead to faster write-erase cycle times and/or can allow the use of lower voltages during these operations.

In some embodiments, gaps 128 are defined at edges of the floating-gate insulator 118, between the floating-gate insulator 118 and an encapsulation layer(s) 130. Moreover, in some embodiments a depth(s) 132 of the gaps 128 (i.e., the edges of the floating-gate insulator 118) may be proximate to boundaries between the source 112 region and the substrate 110 and the drain 114 region and the substrate 110. For example, the gaps 128 may be defined so that they do not overlap the channel 116, thereby reducing or minimizing the impact on the transconductance of the channel 116.

In some embodiments the ends of the floating-gate insulator 118 may be approximately aligned with the boundaries between the source 112 region and the substrate 110 and the drain 114 region and the substrate 110. In some embodiments, the floating-gate insulator 118 has a thickness 134, and the depth(s) 132 of the gaps 128 approximately equals the thickness 134. In an exemplary embodiment, the depth(s) 132 and/or the thickness 134 may be less than 20 nm.

In some embodiments, an atmosphere within the gaps 128 has a pressure less than a pre-determined value. For example, the pre-determined value may be 10⁻⁵ torr. Thus, the gaps 128 may be vacuum gaps. Consequently, in some embodiments the gaps 128 have a dielectric constant of approximately 1.

However, in some embodiments the gaps 128 have a pressure greater than 1 atmosphere, such as a pressure between approximately between 1 and 10 atmospheres. In these embodiments, the gaps 128 include a gas. This gas may be: hydrogen, argon gas, nitrogen gas, and/or a noble gas. Moreover, the pressure in the gaps 128 and the gas may be selected so that the mean free path prevents or reduces the likelihood of avalanche breakdown in the gaps 128 for a given voltage applied between the terminals 126 (i.e., the conductivity of the gaps 128 is bounded).

In some embodiments, the floating-gate layer 120 (and more generally, the charge-collection structure in the memory device 100) is a conductor, such as polysilicon. However, in some embodiments the floating-gate layer 120 may be replaced by a charge-storage layer that is non-conducting. For example, this charge-storage layer may be an insulator, such as a nitride layer. Consequently, in some embodiments the memory device 100 includes a silicon-oxygen-nitride-oxygen-silicon (SONOS) or SONOS-like memory device.

In the preceding discussion, as an illustration memory device 100 has been described as a NAND Flash memory device. As noted previously, in other embodiments memory device 100 may be a NOR Flash memory device. In these embodiments, charge may be stored on the floating-gate layer 120 through hot-electron injection. Moreover, in these embodiments the gaps 128 may overlap a portion of the channel 116. In particular, the gaps 128 may overlap the pinch-off region of the channel 116.

Note that the memory device 100 may include fewer components or additional components. Moreover, two or more components in the memory device 100 may be combined into a single component and/or the position of one or more components may be changed. In some embodiments, the memory device 100 is included in one or more integrated circuits on one or more semiconductor die.

We now describe design of the gaps 128. In particular, the gaps 128 may be designed such that the conductance of the gaps 128 exceeds that of the floating-gate insulator 118 during a program or erase operation, i.e., that most of the current is transported across the gaps 128 as opposed to the floating-gate insulator 118. In addition, the gaps 128 may be designed such that the conductance of either of the gaps 128 is less than that of the floating-gate insulator 118 during a read operation, i.e., that the floating gate 120 is not discharged during the read operation. Consequently, in some embodiments the conductance of either or both of the gaps 128 is larger than a conductance of the floating-gate insulator 118 when a voltage larger than a read-operation voltage is applied to the terminals 126, i.e., between the substrate 110 and the control-gate layer 124. Furthermore, in some embodiments the conductance of either or both of the gaps 128 is less than the conductance of the floating-gate insulator 118 when a voltage less than or equal to a read-operation voltage is applied to the terminals 126.

Moreover, the gaps 128 have a gate capacitance that is lower than that of the floating-gate insulator 118 by a factor proportional to the ratio of the dielectric constant of the floating-gate insulator 118 to that of either of the gaps 128. Consequently, this ratio may be chosen to be large enough to limit the impact on the read-back performance of the memory device 100. In an exemplary embodiment, the ratio of the dielectric constant of the floating-gate insulator 118 to that of either of the gaps 128 is approximately four. In addition, by reducing or eliminating overlap between the gaps 128 and the channel 116, the impact of the gaps 128 on the transconductance of the channel 116 may be reduced or minimized.

In the discussion that follows, the design of gaps 128 having a soft or hard vacuum (which are sometimes referred to as vacuum gaps) are used as an illustrative example. We wish to determine the change in the charge transport across the floating-gate insulator 118 if a portion of the floating-gate insulator 118 is replaced by one or more vacuum gaps. As noted above, to achieve the goal of improving the endurance, the programming and erase currents may flow predominantly through the vacuum gap(s). Moreover, the conductance of the vacuum gap(s) may be less than that of the floating-gate insulator 118 during read operations to retain the stored information and maintain read stability.

Existing analysis of conduction through tunnel barriers includes the Fowler-Nordheim tunneling expression. This expression was determined by applying the Jeffries-Wentzel-Kramers-Brillouin (JWKB) approximation to a triangular energy barrier associated with an insulator (such as the floating-gate insulator 118). However, this analysis only includes the lowering of the energy barrier associated with image charges on the source side of the energy barrier, which can lead to an incorrect dependence on the dielectric constant of the insulator, especially for insulator thicknesses less than 10 nm and/or for high electric-field magnitudes.

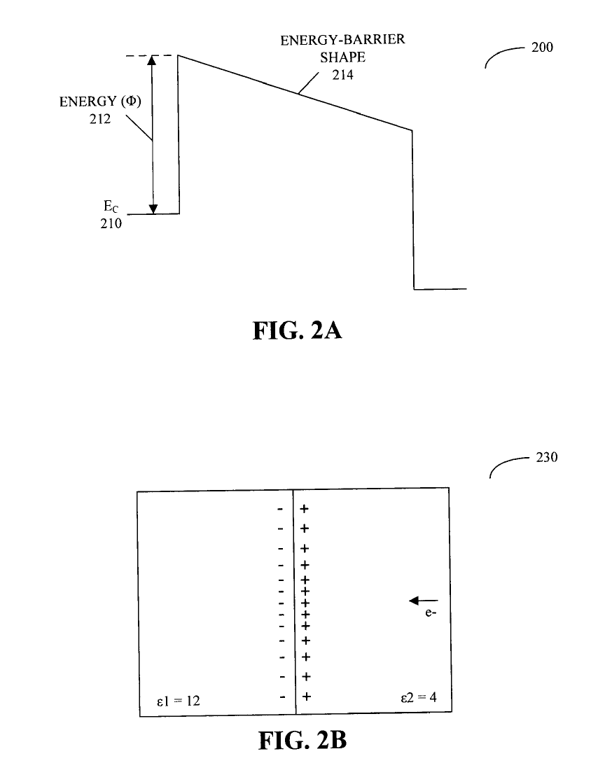

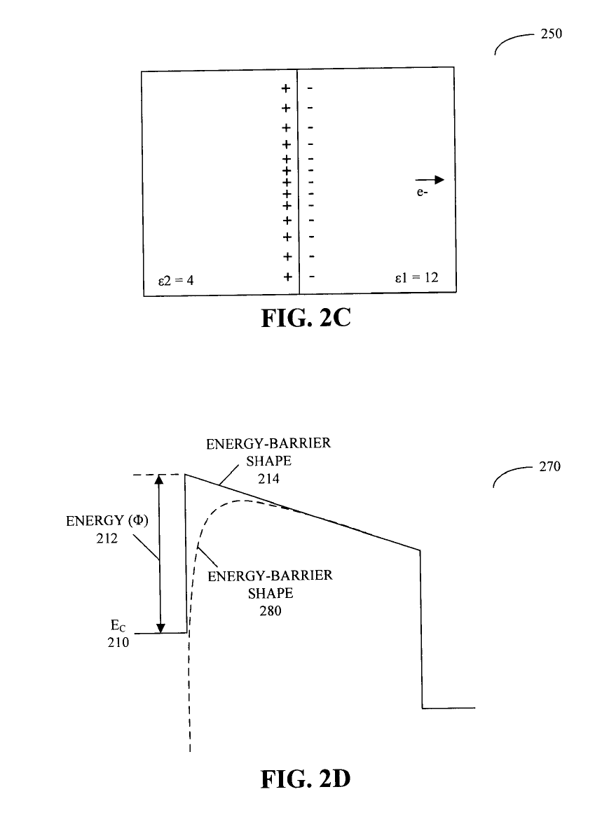

A triangular energy-barrier shape is shown in FIG. 2A, which presents a graph 200 illustrating an embodiment of an energy-barrier shape 214 associated with an insulator. Note that the conduction-band (E_{C}) 210 energy of the silicon on either side of the energy barrier is offset from the lower edge of the conduction-band energy of the insulator by an energy (Φ) 212. Moreover, note that the generally accepted value for Φ is 3.2 eV for silicon dioxide and 4.5 eV for vacuum.

A better approximation to the energy-barrier shape 214 may be obtained by including a symmetric image-potential term, which includes image charges on both sides of the energy barrier. Note that this image-potential term is associated with the polarization or induced charge that occurs when a charge is placed near the boundary between two different dielectrics. FIGS. 2B and 2C present graphs 230 and 250 illustrating embodiments of such boundary polarizations for two configurations of relative dielectric constant, in which a charge in the material with the lower dielectric constant is attracted toward the interface, while a charge in the material with the higher dielectric constant is repelled by the interface. By including this image-potential term, the energy barrier is further reduced. This is shown in FIG. 2D, which presents a graph 270 illustrating an embodiment of an energy-barrier shape 280.

An integral equation provides a compact way to express the symmetric image-potential term as a function of distance (z) in the insulator. In particular,

$$Φ ( z ) = \frac{{q}^{2} β}{2 {ɛ}_{ox}} {\int }_{0}^{∞} \frac{[ {e}^{2 k ( z - d )} + {e}^{2 kz} - 2 β {e}^{- 2 kd} ]}{1 - {β}^{2} {e}^{- 2 kd}} \cdot d k ,$$

where q is the electron charge, k is a wavenumber, d is the insulator thickness, and

$$β = \frac{{ɛ}_{si} - {ɛ}_{ox}}{{ɛ}_{si} + {ɛ}_{ox}}$$

is a function of the permittivity of silicon relative to the permittivity of the insulator. Moreover, in the presence of an electric field F, the energy-barrier shape can be expressed as

V(z)=Φ−qFz−Φ(z).

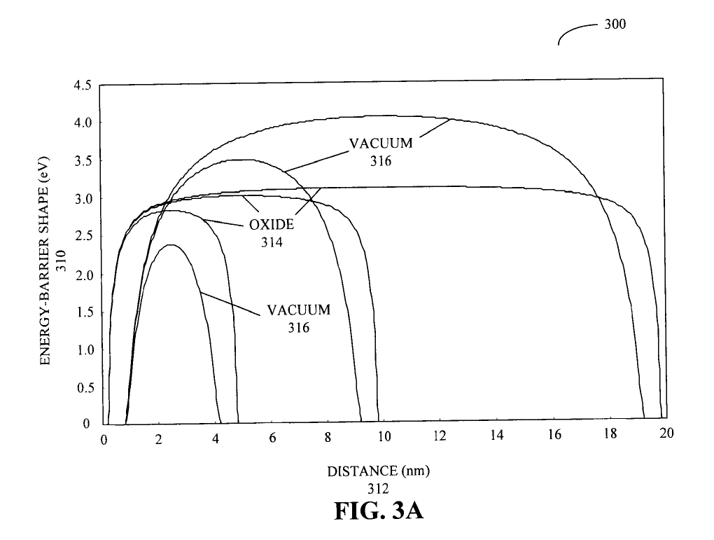

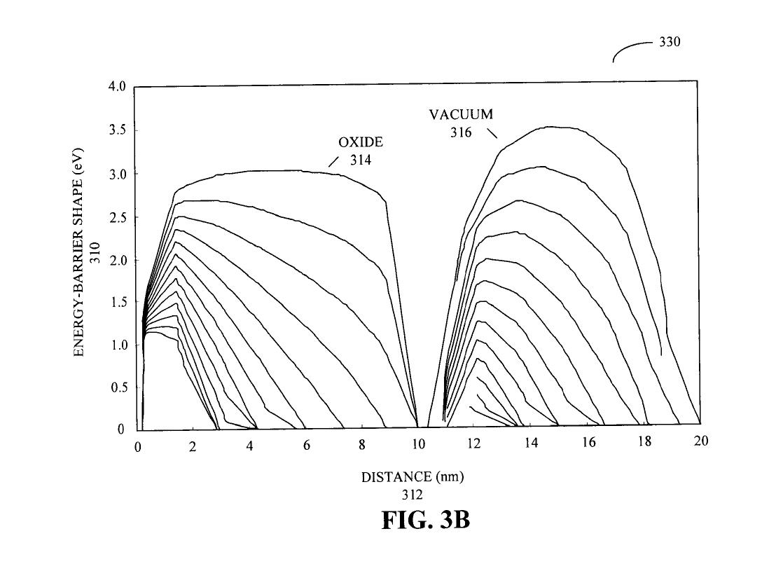

Based on this equation, FIG. 3A presents a graph 300 illustrating an embodiment of energy-barrier shape 310 (in eV) at zero field as a function of distance 312 (in nm) for an oxide 314 insulator and a vacuum 316 gap with thicknesses of 5, 10, and 20 nm. These results indicate that the longer range of the symmetric image-potential term for the vacuum 316 gap leads to a change in behavior of the energy-barrier shape 310 as a function of the thickness of the gap. In particular, for a gap thickness of 20 nm the maximum energy barrier is larger than that for the oxide 314 insulator, and less tunneling current will flow. However, for a gap thickness of 5 nm, the maximum energy barrier is smaller and the energy-barrier shape 310 is narrower than those for the oxide 314 insulator, and more tunneling current will flow. This crossover of the relative tunneling conductivity as a function of thickness is not predicted by the standard Fowler-Nordheim tunneling expression because of approximations in that theory.

FIG. 3B is a graph 330 illustrating an embodiment of energy-barrier shape 310 (in eV) as a function of distance 312 (in nm) and applied voltage (0 to 16 V) for an oxide 314 insulator and a vacuum 316 gap with a thickness of 10 nm. Note that the vacuum 316 gap results have been offset by 10 nm for clarity. Moreover, note that the tunneling current is inversely proportional to the area under the energy-barrier shape 310. At zero voltage (or zero electric field), the vacuum 316 gap has a larger maximum energy barrier and a narrower energy-barrier shape 310. However, the energy-barrier shape 310 of the vacuum 316 gap is more sensitive to the applied voltage (or electric field) especially at the largest applied voltage of 16 V.

To evaluate the relative transmission probability (T) of a conduction-band electron tunneling through these energy barriers, the JWKB approximation can be used along with the previous expression for the energy-barrier shape. In particular,

$$T = exp [ - \frac{\sqrt{2 {m}^{*}}}{π h} {\int }_{0}^{d} d z \sqrt{V ( z ) - Ec} ] ,$$

where m* is the effective mass of the barrier material (i.e., the insulator or the vacuum gap) and h is Planck's constant. Note that m* for an oxide insulator is 0.5 of the electron mass, and that m* for vacuum is the electron mass. Moreover, the tunnel current density (j) can be estimated by integrating the product of T and the density of surface electrons over energies above E_{C}, i.e.,

$$j = \frac{{qm}^{*} {k}_{B} T}{2 {{π}^{2} ( 2 π h )}^{3}} {\int }_{0}^{Φ} d E \cdot T ( E ) \cdot ln ( \frac{1 + exp ( {E}_{FS} - {E}_{C} - E )}{1 + exp ( {E}_{FP} - {E}_{C} - E )} ) ,$$

where k_{B} is Boltzmann's constant, T is 300 K, E_{FS} is the chemical potential of the semiconductor surface (such as that of silicon) on either side of the energy barrier, E_{PS} is the chemical potential of the insulator (such as polysilicon), and E is the energy of the tunneling electron.

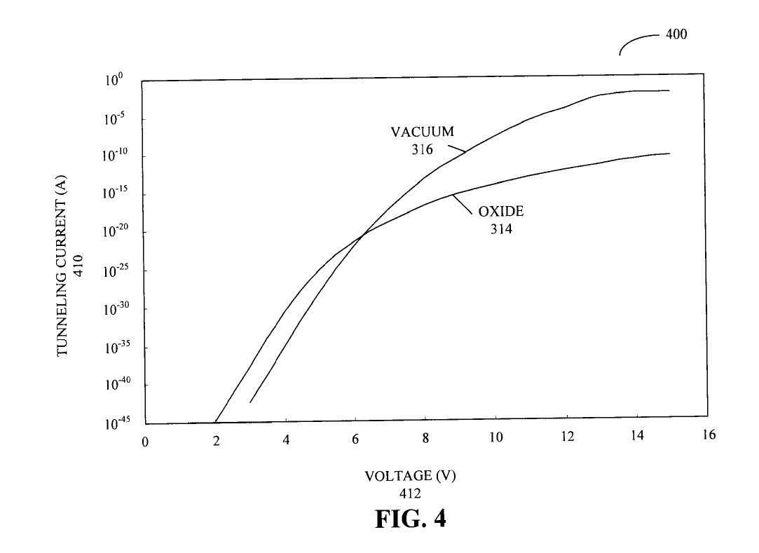

Based on this equation, tunneling currents were calculated for a memory device having: a width of 65 nm, a length of 65 nm, and an insulator thickness of 10 nm. These simulations are shown in FIG. 4, which presents a graph 400 illustrating tunneling current 410 (in A) as a function of voltage 412 (in V) applied to the control gate 124 (FIG. 1) for an embodiment.

As shown in FIG. 4, the vacuum 316 gap provides performance improvement in both the write-erase cycle time and in read-back performance. In particular, for voltages below around 7 V, the vacuum 316 gap has a much lower tunneling current 410 than the oxide 314 insulator. This suggests that adding the vacuum 316 gap will not degrade the read stability or the variation in the retention time as a function of the number of read operations. Moreover, for voltages above around 7 V, the vacuum 316 gap has a substantially increased tunneling current 410 compared to the oxide 314 insulator. Thus, at typical program and erase voltages the tunneling current 410 will flow predominantly through the vacuum 316 gap and the endurance problems experienced by traditional devices can be reduced or avoided. In addition, the increased tunneling current 410 will increase the speed of write and erase operations, thereby reducing the write-erase cycle time. Note that in separate simulations (not shown) the presence of vacuum gaps at the edges of the floating-gate insulator 118 (FIG. 1) are predicted to reduce the saturation current of the memory device 100 (FIG. 1) by 20% for a thickness 134 (FIG. 1) of 10 nm.

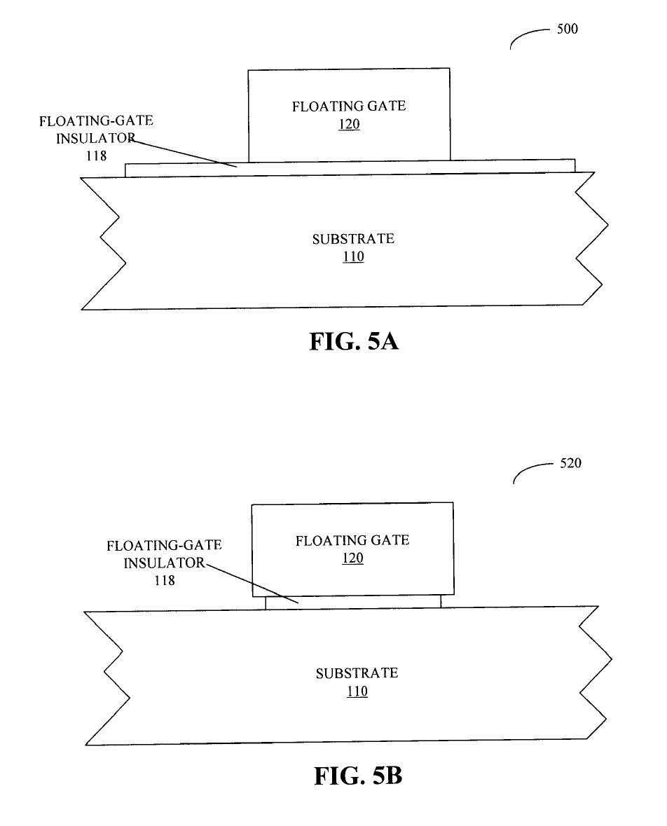

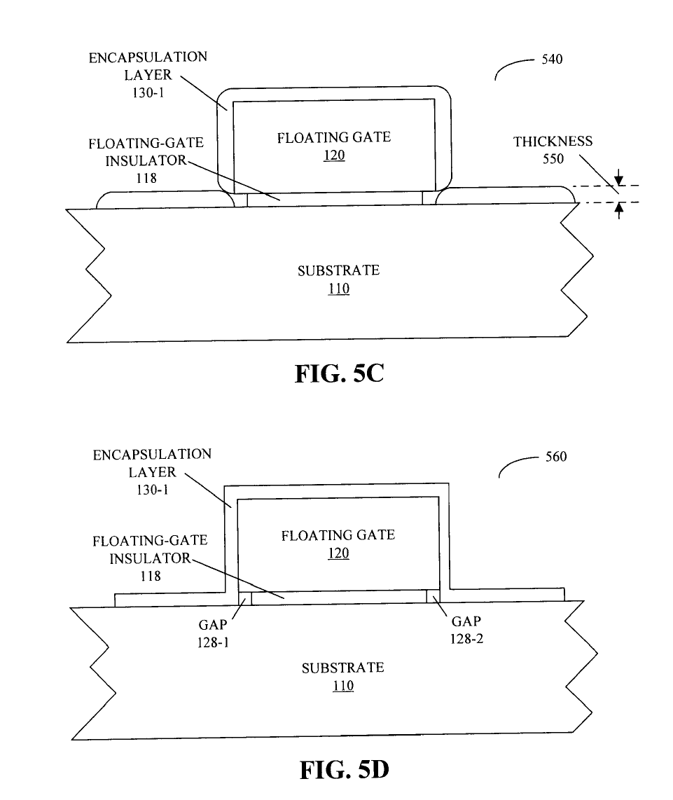

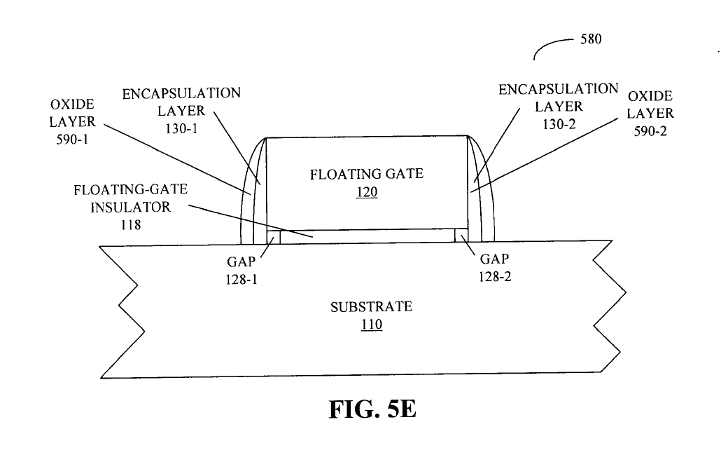

We now describe embodiments of a process for fabricating a memory device. FIG. 5A presents a block diagram illustrating an embodiment 500 of a process for fabricating of a memory device. In this embodiment, a standard fabrication sequence has been completed through the anisotropic etch of floating gate 120.

Then, as shown in FIG. 5B, which presents a block diagram illustrating an embodiment 520 of a process for fabricating of the memory device, the floating-gate insulator 118 may be under cut to produce the gap depth(s). For example, the floating-gate insulator 118 may isotropically etched.

Next, as shown in FIG. 5C, which presents a block diagram illustrating an embodiment 540 of a process for fabricating of the memory device, the encapsulation layer 130-1 may be deposited. For example, this non-conformal layer may be fabricated using low-pressure chemical-vapor deposition. Moreover, the encapsulation layer 130-1 may be phosphosilicate or boro phosphosilicate. During deposition, the encapsulation layer 130-1 will grow laterally until it meets a neighboring structure forming a thin crack or ‘cusp’ at the boundary. In some embodiments, the encapsulation layer 130-1 has a thickness 550 which is 2-3 times the thickness 134 (FIG. 1). For example, the thickness 550 may be 30 nm.

After deposition, the encapsulation layer 130-1 may be vacuum reflowed, as shown in FIG. 5D which presents a block diagram illustrating an embodiment 560 of a process for fabricating of the memory device. In particular, during a high-temperature anneal the encapsulation layer 130-1 may flow together at the cusps, thereby sealing the gaps 128. Note that the atmospheric condition in the gaps 128 may be set before, during, or after this operation. For example, a vacuum may be generated or improved by activation annealing of the memory device following diffusion-region implantation. In an exemplary embodiment, a silicon substrate is used as a getter for oxygen gas, which will oxidize the surface of the silicon, thereby reducing the pressure of the residual gas contained within the gaps 128 (FIG. 1).

Then, as shown in FIG. 5E, which presents a block diagram illustrating an embodiment 580 of a process for fabricating of the memory device, the encapsulation layer 130 may be etched and an oxide layer 590 may be deposited. Note that this oxide layer may function as a spacer. After completing this operation, the remainder of the standard process flow for the memory device may be performed.

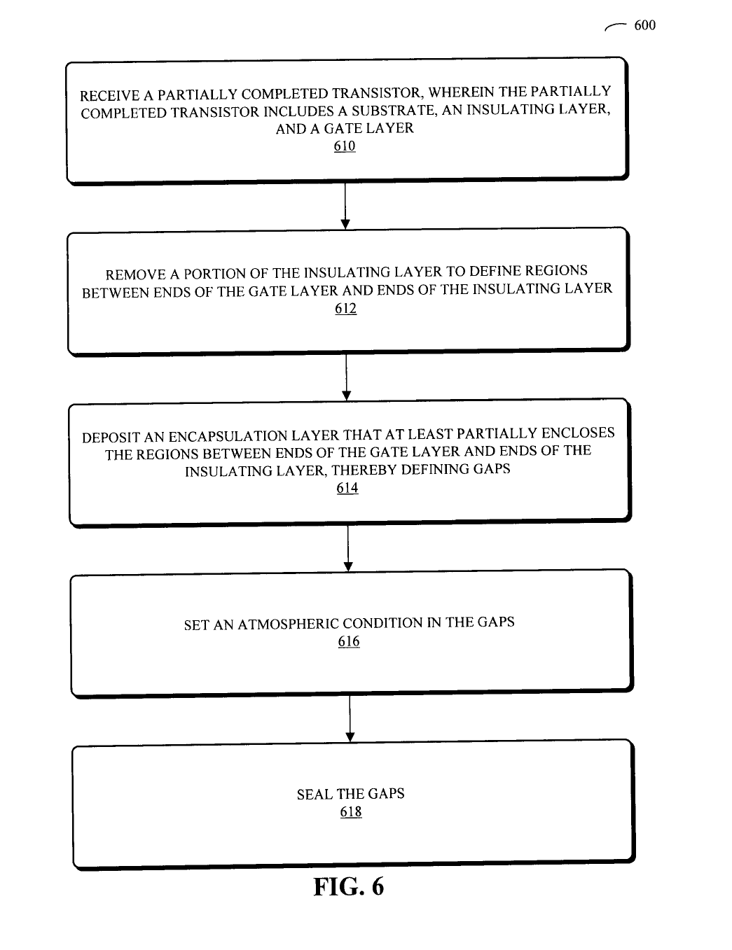

FIG. 6 presents a flow chart illustrating an embodiment of a process 600 for fabricating a memory device, such as a transistor. During this process, a partially completed transistor is received (610). This partially completed transistor includes the substrate, the insulator layer, and the gate layer. Note that the substrate has the surface, where the first region of the substrate is doped with the first type of dopant and the second region of the substrate is doped with the first type of dopant, where the third region of the substrate between the first region and the second region is doped with the second type of dopant, and where the third region is associated with the channel having the voltage-dependent transconductance. Moreover, the insulator layer is deposited above at least the portion of the surface, where the portion of the surface substantially includes the third region, and the gate layer deposited above the insulator layer.

Next, a portion of the insulator layer is removed to define regions between ends of the gate layer and ends of the insulator layer (612). Note that after removing the portion of the insulator layer, one end of the insulator layer is proximate to the boundary between the first region and the third region and another end of the insulator layer is proximate to the boundary between the second region and the third region.

Then, an encapsulation layer that at least partially encloses the regions between ends of the gate layer and ends of the insulator layer is deposited (614), thereby defining gaps. Moreover, an atmospheric condition is set in the gaps (616) and the gaps are sealed (618).

In some embodiments of the process 600 there may be fewer or additional operations. Moreover, two or more operations can be combined into a single operation, and/or a position of one or more operations may be changed.

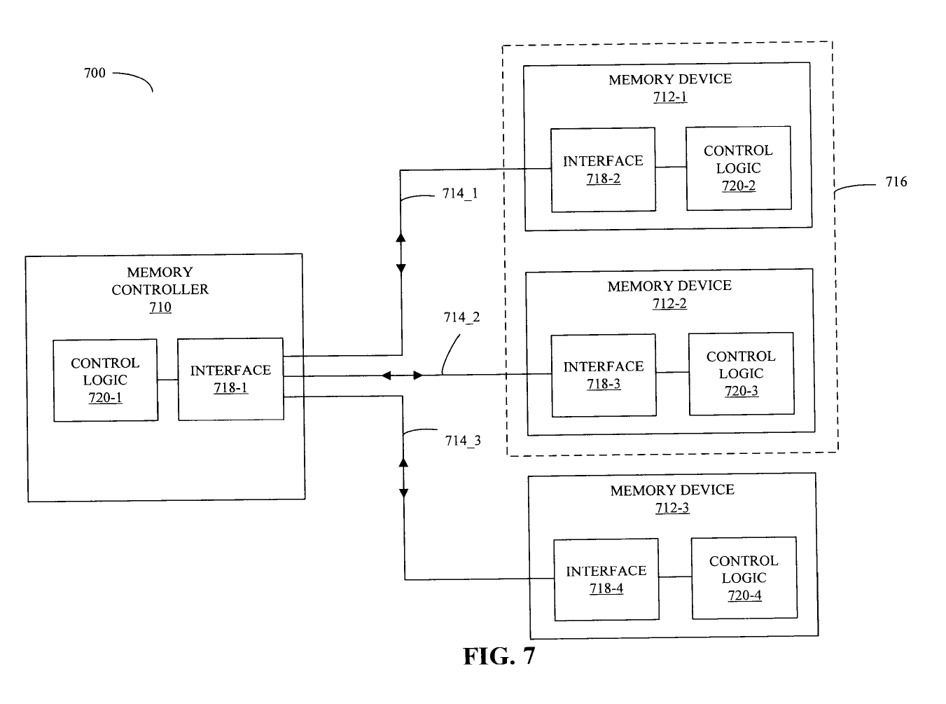

We now describe embodiments of devices and systems that include one or more of the transistors. FIG. 7 presents a block diagram illustrating an embodiment of a memory system 700. This memory system includes at least one memory controller 710 and one or more memory devices 712, such as one or more memory modules. While FIG. 7 illustrates memory system 700 having one memory controller 710 and three memory devices 712, other embodiments may have additional memory controllers and fewer or more memory devices 712. Moreover, while memory system 700 illustrates memory controller 710 coupled to multiple memory devices 712, in other embodiments two or more memory controllers may be coupled to one another. Note that memory controller 710 and one or more of the memory devices 712 may be implemented on the same or different integrated circuits, and that these one or more integrated circuits may be included in a chip-package.

In some embodiments, the memory controller 710 is a local memory controller (such as a Flash memory controller) and/or is a system memory controller (which may be implemented in a microprocessor). Memory controller 710 may include control logic 720-1 and an I/O interface 718-1. Optionally, one or more of memory devices 712 may include control logic 720 and at least one of interfaces 718. However, in some embodiments some of the memory devices 712 may not have control logic 720 and/or one of the interfaces 718. Moreover, memory controller 710 and/or one or more of memory devices 712 may include more than one of the interfaces 718, and these interfaces may share one or more control logic 720 circuits. Note that two or more of the memory devices 712, such as memory devices 712-1 and 712-2, may be configured as a memory bank 716.

Memory controller 710 and memory devices 712 are coupled by one or more links 714. While memory system 700 illustrates three links 714, other embodiments may have fewer or more links 714. These links may include: wired, optical and/or wireless communication. Furthermore, links 714 may be used for bi-directional and/or uni-directional communications between the memory controller 710 and one or more of the memory devices 712. For example, bi-directional communication between the memory controller 710 and a given memory device may be simultaneous (full-duplex communication). Alternatively, the memory controller 710 may transmit information (such as a data packet which includes a command) to the given memory device, and the given memory device may subsequently provide requested data to the memory controller 710, i.e., a communication direction on one or more of the links 714 may alternate (half-duplex communication). Note that one or more of the links 714 and corresponding transmit circuits and/or receive circuits may be dynamically configured, for example, by one of the control logic 720 circuits, for bi-directional and/or unidirectional communication. Moreover, in some embodiments, transmitting and receiving may be synchronous and/or asynchronous.

In some embodiments, data may be communicated on one or more of the links 714 using one or more sub-channels associated with one or more carrier frequencies fᵢ. Moreover, a given sub-channel may have an associated: range of frequencies, a frequency band, or groups of frequency bands (henceforth referred to as a frequency band). For example, a baseband sub-channel is associated with a first frequency band and a passband sub-channel is associated with a second frequency band. Note that, if at least one of the links 714 is AC-coupled, the baseband sub-channel may not contain DC (i.e., does not include 0 Hz).

In some embodiments, frequency bands for adjacent sub-channels may partially or completely overlap, or may not overlap. For example, there may be partial overlap of neighboring frequency bands, which occurs in so-called approximate bit loading. Moreover, in some embodiments signals on adjacent sub-channels may be orthogonal.

Signals carried on these sub-channels may be time-multiplexed, frequency multiplexed, and/or encoded. Thus, in some embodiments the signals are encoded using: time division multiple access, frequency division multiple access, and/or code division multiple access. Moreover, in some embodiments signals are communicated on the links 714 using discrete multi-tone communication (such as Orthogonal Frequency Division Multiplexing).

Note that encoding should be understood to include modulation coding and/or spread-spectrum encoding, for example, coding based on binary pseudorandom sequences (such as maximal length sequences or m-sequences), Gold codes, and/or Kasami sequences. Furthermore, modulation coding may include bit-to-symbol coding in which one or more data bits are mapped together to a data symbol, and symbol-to-bit coding in which one or more symbols are mapped to data bits. For example, a group of two data bits can be mapped to: one of four different amplitudes of an encoded data signal; one of four different phases of a sinusoid; or a combination of one of two different amplitudes of a sinusoid and one of two different phases of the same sinusoid (such as in quadrature amplitude modulation or QAM).

In general, the modulation coding may include: amplitude modulation, phase modulation, and/or frequency modulation, such as pulse amplitude modulation (PAM), pulse width modulation, and/or pulse code modulation. For example, the modulation coding may include: two-level pulse amplitude modulation (2-PAM), four-level pulse amplitude modulation (4-PAM), eight-level pulse amplitude modulation (8-PAM), sixteen-level pulse amplitude modulation (16-PAM), two-level on-off keying (2-OOK), four-level on-off keying (4-OOK), eight-level on-off keying (8-OOK), and/or sixteen-level on-off keying (16-OOK).

In some embodiments, the modulation coding includes non-return-to-zero (NRZ) coding. Moreover, in some embodiments the modulation coding includes two-or-more-level QAM. Note that the different sub-channels communicated on the links 714 may be encoded differently and/or the modulation coding may be dynamically adjusted, for example, based on a performance metric associated with communication on one or more of the links 714. This performance metric may include: a signal strength (such as a signal amplitude or a signal intensity), a mean square error (MSE) relative to a target (such as a detection threshold, a point in a constellation diagram, and/or a sequence of points in a constellation diagram), a signal-to-noise ratio (SNR), a bit-error rate (BER), a timing margin, and/or a voltage margin.

In some embodiments, one or more of the links 714 is a separate command link (or communication channel), which communicate commands to the memory devices 712. This separate link: may be wireless, optical or wired; may have a lower data rate than the data rates associated with one or more of the sub-channels; may use one or more different carrier frequencies than are used in the data sub-channels; and/or may use a different modulation technique than is used in the data sub-channels.

In some embodiments, either a local memory controller and/or a system memory controller issue refresh commands to prevent the loss of stored data. For example, control logic 720-1 may provide refresh commands to at least one of the memory devices 712, instructing at least one of the memory devices 712 to refresh at least a portion of data stored in storage cells on the memory device. Refreshing data can prevent data loss due to the leakage of charge from the storage cells in memory devices, such as Flash memory. Consequently, for a given number of program/erase cycles, as long as stored data is refreshed before the associated data retention time is exceeded, the stored data may be recovered. While refresh results in lower data retention times (because the degradation in the Flash memory is in general irreversible), it also increases the maximum number of program/erase cycles or the endurance of the Flash memory. (Eventually, the data retention time becomes too short and it is not possible to refresh stored data before it is lost. At this point, the Flash memory is no longer usable.)

Note that data stored in one or more storage cells on at least one of the memory devices 712 may be refreshed based on a usage history of the memory device, such as the number of program/erase cycles and/or a number of read operations performed on or proximate to the one or more storage cells. Moreover, the refresh interval or refresh rate may be selected such that the retention time is acceptable for a given application. For example, each storage cell on a memory device may be refreshed more often than its worst-case (i.e., smallest) data retention time. Consequently, the refresh interval may be fixed, may be scheduled (such as at a given time every hour, multiple hours, day, week, and/or month), and/or may occur after an elapsed time since a previous refresh.

However, in some embodiments the refresh interval and the refresh rate are variable, thereby taking advantage of characteristics of memory such as Flash memory. For example, at least one control logic 720 may issue commands to refresh stored data at a sequence of refresh intervals, where a given refresh interval in the sequence of refresh intervals is smaller than an initial refresh interval and the given refresh interval is less than a preceding refresh interval in the sequence of refresh intervals. Moreover, a refresh rate corresponding to the sequence of refresh intervals may progressively increase based on the number of operations performed on or proximate to the storage cells.

In some embodiments, additional techniques are used to recover or prevent the loss of data communicated between the memory controller 710 and the memory devices 712 and/or the loss of stored data. For example, at least a portion of the data communicated between these components and/or the stored data may include error-detection-code (EDC) information and/or error-correction-code (ECC) information. This EDC and/or ECC information may be pre-existing or may dynamically generated (i.e., in real time).

In some embodiments, the ECC information includes a Bose-Chaudhuri-Hochquenghem (BCH) code. Note that BCH codes are a sub-class of cyclic codes. In exemplary embodiments, the ECC information includes: a cyclic redundancy code (CRC), a parity code, a Hamming code, a Reed-Solomon code, and/or another error checking and correction code.

Consequently, in some embodiments at least some of the receive circuits in the memory system 700 implement error detection and/or correction. For example, errors associated with communication may be detected by performing a multi-bit XOR operation in conjunction with one or more parity bits in the signals communicated on the links 714.

Moreover, control logic 720 may take a variety of remedial actions in the event of an error or a degradation of one or more of the performance metrics during communication between the memory controller 710 and one or more of the memory devices 712. These remedial actions may include: re-transmitting previous data; transmitting previous or new data (henceforth referred to as data) using an increased transmission power than the transmission power used in a previous transmission; reducing the data rate in one or more of the sub-channels relative to the data rate used in a previous transmission; transmitting data with reduced intersymbol interference (for example, with blank intervals inserted before and/or after the data); transmitting data at a single clock edge (as opposed to dual-data-rate transmission); transmitting data with at least a portion of the data including ECC or EDC; transmitting data using a different encoding or modulation code than the encoding used in a previous transmission; transmitting data after a pre-determined idle time; transmitting data to a different receive circuit; transmitting data to another device (which may attempt to forward the data); and/or changing the number of sub-channels. Note that in some embodiments one or more of these adjustments are performed: continuously; as need based (for example, based on one or more of the performance metrics); and/or after a pre-determined time interval.

In some embodiments, the remedial action (and more generally adjustments to one or more of the sub-channels) is based on control information that is exchanged between the memory controller 710 and one or more of the memory devices 712. This control information may be exchanged using in-band communication (i.e., via the frequency bands used to communicate data signals) and/or out-of-band communication (for example, using the separate link).

In some embodiments, the remedial action and/or adjustments involve an auto-negotiation technique. During this auto-negotiation technique, a receive circuit in one of the components in the memory system 700 may provide feedback to a transmit circuit in another component on the efficacy of any changes to the signals on a sub-channel. Based on this feedback, the transmit circuit may further modify these signals, i.e., may perform the remedial action.

Devices and circuits described herein may be implemented using computer aided design tools available in the art, and embodied by computer-readable files containing software descriptions of such circuits. These software descriptions may be: at behavioral, register transfer, logic component, transistor and layout geometry level descriptions. Moreover, the software descriptions may be stored on storage media or communicated by carrier waves.

Data formats in which such descriptions may be implemented include, but are not limited to: formats supporting behavioral languages like C, formats supporting register transfer level RTL languages like Verilog and VHDL, formats supporting geometry description languages (such as GDSII, GDSIII, GDSIV, CIF, and MEBES), and other suitable formats and languages. Moreover, data transfers of such files on machine-readable media including carrier waves may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

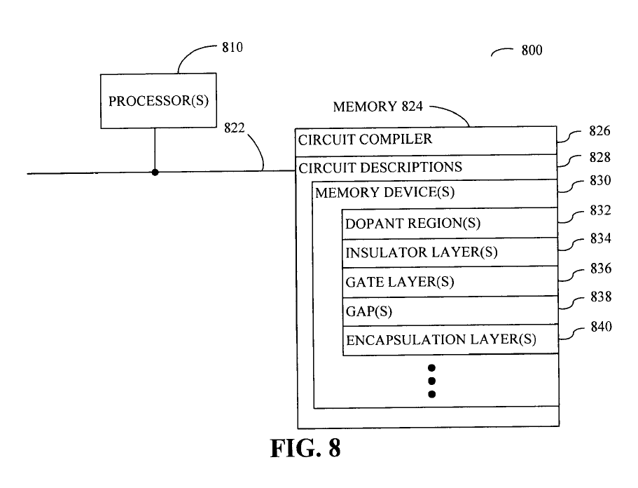

FIG. 8 presents a block diagram illustrating an embodiment of a system 800 that stores such computer-readable files. This system may include at least one data processor or central processing unit (CPU) 810, memory 824 and one or more signal lines or communication busses 822 for coupling these components to one another. Memory 824 may include high-speed random access memory and/or non-volatile memory, such as: ROM, RAM, EPROM, EEPROM, Flash, one or more smart cards, one or more magnetic disc storage devices, and/or one or more optical storage devices.

Memory 824 may store a circuit compiler 826 and circuit descriptions 828.

Circuit descriptions 828 may include descriptions for the memory device, circuits, or a subset of the circuits discussed above with respect to FIG. 1. In particular, circuit descriptions 828 may include circuit descriptions of: one or more memory devices 830, including: one or more dopant regions 832, one or more insulator layers 834, one or more gate layers 836, one or more gaps 838, and/or one or more encapsulation layers 840.

In some embodiments, system 800 includes fewer or additional components. Moreover, two or more components can be combined into a single component, and/or a position of one or more components may be changed.

While refresh of Flash memory has been used as an illustration in the preceding discussion, in other embodiments the device design (i.e., the gaps in the insulator layer) and/or the fabrication technique may be applied to a variety of solid-state memory devices and, more generally, to memory media which are susceptible to charge leakage associated with insulator-layer defects.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

1. A transistor, comprising:
a substrate having a surface, wherein a first region and a second region of the substrate are doped with a first type of dopant, wherein a third region of the substrate between the first region and the second region is doped with a second type of dopant, and wherein the third region is associated with a channel having a voltage-dependent transconductance;
an insulator layer deposited above at least a portion of the surface, wherein the portion of the surface substantially includes the third region, wherein the insulator layer has a first end and a second end, and wherein the first end is approximately aligned with a boundary between the first region and the third region and the second end is approximately aligned with a boundary between the second region and the third region;
a gate layer deposited above the insulator layer, wherein the gate layer has a third end and a fourth end; and
an encapsulation layer enclosing the first end and the second end, wherein the transistor includes a first gap between the first end and the encapsulation layer and a second gap between the second end and the encapsulation layer,
wherein a given gap, which can be the first gap or the second gap, has a depth relative to a given end of the gate layer, which can be the third end or the fourth end.

2. The transistor of claim 1, wherein an atmosphere within the given gap has a pressure less than a pre-determined value.

3. The transistor of claim 2, wherein the pre-determined value is 10⁻⁵ ton.

4. The transistor of claim 1, wherein the given gap includes argon gas or nitrogen gas.

5. The transistor of claim 1, wherein the given gap includes a noble gas.

6. The transistor of claim 1, wherein the given gap includes a gas having a pressure approximately between 1 and 10 atmospheres.

7. The transistor of claim 1, wherein the given gap has a dielectric constant of approximately 1.

8. The transistor of claim 1, wherein the given gap does not overlap the channel.

9. The transistor of claim 1, wherein the insulator layer has a thickness, and wherein the depth of the given gap approximately equals the thickness.

10. The transistor of claim 1, wherein the depth of the given gap is less than 20 nm.

11. The transistor of claim 1, wherein the first gap and the second gap are to reduce tunneling current-induced defects in the insulator layer.

12. The transistor of claim 1, wherein the first gap and the second gap are to improve endurance of the transistor.

13. The transistor of claim 1, wherein the first gap and the second gap are to improve reliability of the transistor.

14. The transistor of claim 1, wherein the first gap and the second gap are to reduce a write-erase cycle time without increasing a leakage current between the gate layer and the substrate.

15. The transistor of claim 1, wherein the first gap and the second gap are to reduce a write-erase cycle time without degrading retention of data stored on the gate layer.

16. (canceled)

17. The transistor of claim 1, wherein gate layer is a conductor.

18. The transistor of claim 1, further comprising another insulator layer above the gate layer and a control-gate layer above the other insulator layer.

19. The transistor of claim 18, wherein gate layer is an insulator.

20. The transistor of claim 1, wherein a conductance of the given gap is larger than a conductance of the insulator layer when a voltage larger than a read-operation voltage is applied between the substrate and a control-gate layer.

21. The transistor of claim 1, wherein a conductance of the given gap is less than a conductance of the insulator layer when a voltage less than or equal to a read-operation voltage is applied between the substrate and a control-gate layer.

22. A programmable memory device, comprising:
a field-effect transistor having a source and a drain at opposite ends of a channel, wherein the field-effect transistor is defined on a substrate,
wherein an insulator layer in the field-effect transistor is deposited above at least a portion of a surface of the substrate,
wherein a first end of the insulator layer is approximately aligned with a boundary between the source and the channel, and a second end of the insulator layer is approximately aligned with a boundary between the drain and the channel, and
wherein a gate layer in the field-effect transistor is deposited above the insulator layer; and
an encapsulation layer enclosing ends of the gate layer and the insulator layer thereby defining gaps between the first and second ends of the insulator layer and the gate layer, wherein the gaps extend from ends of the gate layer to approximately the channel.

23. An integrated circuit, comprising:
a substrate having a surface; and
multiple transistors on the substrate, wherein a given transistor includes:
a first region of the substrate which is doped with a first type of dopant and a second region of the substrate which is doped with the first type of dopant, wherein a third region of the substrate between the first region and the second region is doped with a second type of dopant, and wherein the third region is associated with a channel having a voltage-dependent transconductance;
an insulator layer deposited above at least a portion of the surface, wherein the portion of the surface substantially includes the third region, wherein the insulator layer has a first end and a second end, and wherein the first end is approximately aligned with a boundary between the first region and the third region and the second end is approximately aligned with a boundary between the second region and the third region;
a gate layer deposited above the insulator layer, wherein the gate layer has a third end and a fourth end; and
an encapsulation layer enclosing the first end and the second end, wherein the transistor includes a first gap between the first end and the encapsulation layer and a second gap between the second end and the encapsulation layer,
wherein a given gap, which can be the first gap or the second gap, has a depth relative to a given end of the gate layer, which can be the third end or the fourth end.

24. A system, comprising:
a memory controller; and
a memory device, wherein the memory device includes:
a substrate having a surface; and
multiple transistors on the substrate, wherein a given transistor includes:
a first region of the substrate which is doped with a first type of dopant and a second region of the substrate which is doped with the first type of dopant, wherein a third region of the substrate between the first region and the second region is doped with a second type of dopant, and wherein the third region is associated with a channel having a voltage-dependent transconductance;
an insulator layer deposited above at least a portion of the surface, wherein the portion of the surface substantially includes the third region, wherein the insulator layer has a first end and a second end, and wherein the first end is approximately aligned with a boundary between the first region and the third region and the second end is approximately aligned with a boundary between the second region and the third region;
a gate layer deposited above the insulator layer, wherein the gate layer has a third end and a fourth end; and
an encapsulation layer enclosing the first end and the second end, wherein the transistor includes a first gap between the first end and the encapsulation layer and a second gap between the second end and the encapsulation layer,
wherein a given gap, which can be the first gap or the second gap, has a depth relative to a given end of the gate layer, which can be the third end or the fourth end.

25. A chip package, comprising an integrated circuit, wherein the integrated circuit includes:
a substrate having a surface; and
multiple transistors on the substrate, wherein a given transistor includes:
a first region of the substrate which is doped with a first type of dopant and a second region of the substrate which is doped with the first type of dopant, wherein a third region of the substrate between the first region and the second region is doped with a second type of dopant, and wherein the third region is associated with a channel having a voltage-dependent transconductance;
an insulator layer deposited above at least a portion of the surface, wherein the portion of the surface substantially includes the third region, wherein the insulator layer has a first end and a second end, and wherein the first end is approximately aligned with a boundary between the first region and the third region and the second end is approximately aligned with a boundary between the second region and the third region;
a gate layer deposited above the insulator layer, wherein the gate layer has a third end and a fourth end; and
an encapsulation layer enclosing the first end and the second end, wherein the transistor includes a first gap between the first end and the encapsulation layer and a second gap between the second end and the encapsulation layer,
wherein a given gap, which can be the first gap or the second gap, has a depth relative to a given end of the gate layer, which can be the third end or the fourth end.

26. A computer readable medium containing first data representing a transistor that includes:
a first region of a substrate doped with a first type of dopant and a second region of the substrate doped with the first type of dopant; wherein a third region of the substrate between the first region and the second region is doped with a second type of dopant, and wherein the third region is associated with a channel having a voltage-dependent transconductance;
an insulator layer deposited above at least a portion of a surface of the substrate, wherein the portion of the surface substantially includes the third region, wherein the insulator layer has a first end and a second end, and wherein the first end is approximately aligned with a boundary between the first region and the third region and the second end is approximately aligned with a boundary between the second region and the third region;
a gate layer deposited above the insulator layer, wherein the gate layer has a third end and a fourth end; and
an encapsulation layer enclosing the first end and the second end, wherein the transistor includes a first gap between the first end and the encapsulation layer and a second gap between the second end and the encapsulation layer,
wherein a given gap, which can be the first gap or the second gap, has a depth relative to a given end of the gate layer, which can be the third end or the fourth end.

27. A method for fabricating a transistor, comprising:
receiving a partially completed transistor, wherein the partially completed transistor includes:
a substrate having a surface, wherein a first region of the substrate is doped with a first type of dopant and a second region of the substrate is doped with the first type of dopant, wherein a third region of the substrate between the first region and the second region is doped with a second type of dopant, and wherein the third region is associated with a channel having a voltage-dependent transconductance;
an insulator layer deposited above at least a portion of the surface, wherein the portion of the surface substantially includes the third region;
a gate layer deposited above the insulator layer, wherein the gate layer has a first end and a second end;
removing a portion of the insulator layer to define a fourth region between the first end of the gate layer and a third end of the insulator layer and to define a fifth region between the second end of the gate layer and a fourth end of the insulator layer, wherein the third end is approximately aligned with a boundary between the first region and the third region and the fourth end is approximately aligned with a boundary between the second region and the third region;
depositing an encapsulation layer that at least partially encloses the fourth region and the fifth region, thereby defining a first gap between the third end and the encapsulation layer and a second gap between the fourth end and the encapsulation layer;
setting an atmospheric condition in the first gap and the second gap; and
sealing the first gap and the second gap.
